(19) United States
(12) Patent Application Publication
(10) Pub. No.: US 2026/0121763 A1
(43) Pub. Date: Apr. 30, 2026

(54) COMMUNICATION SYSTEM, RECEIVER, EQUALIZATION SIGNAL PROCESSING CIRCUIT, METHOD, AND COMPUTER READABLE MEDIUM

(71) Applicant: NEC Corporation, Minato-ku, Tokyo (JP)

(72) Inventors: Manabu Arikawa, Tokyo (JP); Masaki Sato, Tokyo (JP)

(73) Assignee: NEC Corporation, Minato-ku, Tokyo (JP)

(21) Appl. No.: 18/835,797

(22) PCT Filed: Feb. 25, 2022
(86) PCT No.: PCT/JP2022/007907

§ 371 Date: Aug. 5, 2024

(51) Int. Cl. H04B 10/61; H03H 17/06; H03H 21/00; H04J 14/06

(52) U.S. Cl. CPC H04B 10/6161; H03H 17/06; H03H 21/0012; H04J 14/06; H03H 2021/0092

(57) ABSTRACT

A first filter performs compensation for first distortion being included in a reception signal being coherent-received, with respect to the reception signal and a complex conjugate signal of the reception signal, and outputs the reception signal and the complex conjugate signal that are subjected to compensation for the first distortion. A second filter being included in a filter group receives, as input signals, the reception signal and the complex conjugate signal that are subjected to compensation for the first distortion, performs compensation for second distortion being included in the reception signal, and outputs the reception signal being subjected to compensation for the second distortion. A coefficient updating means adaptively controls a filter coefficient of the second filter, based on a difference between an output signal being output from the filter group and a predetermined value of the output signal.

### TECHNICAL FIELD

The present disclosure relates to a communication system, a receiver, an equalization signal processing circuit, an equalization signal processing method, and a computer readable medium.

### BACKGROUND ART

In order to achieve high spectral utilization efficiency in optical fiber communication, multi-level modulation such as high-order quadrature amplitude modulation (QAM) is adopted. Since introduction of coherent reception technology, it has become possible to perform flexible equalization signal processing on a receiver side by digital signal processing, such as by collectively compensating for chromatic dispersion accumulated in an optical fiber transmission path at the receiver side. Generally, however, a high-order multi-level modulation signal is susceptible to distortion. For this reason, distortion caused by imperfection of a component in a transceiver or the like is becoming a new bottleneck in promoting high multi-level.

As a related art, Non Patent Literature 1 discloses receiver side equalization digital signal processing that performs equalization of a coherent-received QAM signal. FIG. 8 illustrates an example of the receiver side equalization digital signal processing described in Non Patent Literature 1. The equalization digital signal processing includes a chromatic dispersion compensation 501, a polarization demultiplexing 502, and a carrier phase compensation 503. It is assumed that reception signals of each of X/Y polarization being coherent-received by a receiver are x₁ and x₂. Assuming that an in-phase component (I) and a quadrature component (Q) of each of polarization are xⱼᵢ and x_{jQ}, the reception signal is represented by xⱼ=xⱼᵢ+ix_{jQ}.

The chromatic dispersion compensation 501 compensates for chromatic dispersion occurring when an optical signal propagates through an optical fiber. The chromatic dispersion compensation 501 includes a static complex signal input complex coefficient filter being independent of each polarization. A coefficient of the static filter included in the chromatic dispersion compensation 501 is determined in such a way as to have an inverse characteristic of chromatic dispersion determined from an accumulated chromatic dispersion amount.

The polarization demultiplexing 502 compensates for a polarization state variation and polarization mode dispersion that occur in an optical signal during propagation in an optical fiber. The polarization demultiplexing 502 includes a 2×2 complex signal input complex coefficient multi-input multi-output (MIMO) filter having a cross term between polarized waves. FIG. 9 illustrates a 2×2 MIMO filter used for the polarization demultiplexing 502. A MIMO filter 600 includes, for example, 2×2 finite impulse response (FIR) filters 601. A coefficient of each of the FIR filters 601 is represented by h₁₁, h₁₂, h₂₁, and h₂₂.

The polarization state variation occurring in an optical signal during propagation in an optical fiber changes with time depending on an external environment. A coefficient updating unit 510 adaptively controls the coefficient of each FIR filter 601 in such a way as to follow the polarization state variation, based on an input and an output of the 2×2 MIMO filter (polarization demultiplexing 502). In the polarization demultiplexing 502, an algorithm such as a constant modulus algorithm (CMA), a data-aided least mean square (DALMS) algorithm, or a decision-directed least mean square (DDLMS) algorithm is used for coefficient update. These algorithms are algorithms of updating the coefficient in such a way as to minimize average magnitude of a difference between a filter output and a desired state. In these algorithms, a coefficient update amount is calculated by using an input and an output of a filter.

The carrier phase compensation 503 compensates for a frequency offset and a phase offset between a carrier frequency of a transmitted optical signal and local oscillator light on the receiver side. The carrier phase compensation 503 includes a complex signal input complex coefficient filter that performs phase rotation on the reception signal independently for each polarization. A phase-locked loop (PLL) 520 determines a phase rotation amount of the carrier phase compensation 503. After the carrier phase compensation, signals y₁ and y₂ of each polarization in which various pieces of distortion are compensated for are acquired.

The receiver side equalization digital signal processing illustrated in FIG. 8 is difficult to compensate for IQ distortion occurring in a transmitter or receiver, such as a mismatch in average signal strength between IQ components (IQ imbalance), a time offset between IQ components (IQ skew), and a quadrature offset between IQ components (IQ phase offset). This is because a complex signal input complex coefficient filter such as the MIMO filter illustrated in FIG. 9 is difficult to provide an independent response for each IQ component. In this sense, the complex signal input complex coefficient filter is referred to as strictly linear (SL).

In order to compensate for the IQ distortion occurring in the transmitter or receiver, a filter capable of handling the IQ components independently is required. Such a filter is, for example, a MIMO filter with a real coefficient, in which a signal of a real number of each IQ component is input and output. For example, when such a filter is applied to a signal of one polarization, a 2×2 MIMO filter with real coefficient in which a signal of a real number of two IQ components is input and output is used. The MIMO filter with the real coefficient is equivalent to a filter in which a complex signal and a complex conjugate thereof are as an input and a complex signal acquired by convolving complex coefficient responses with respect thereto and adding the resultants is as an output. These filters are referred to as widely linear (WL).

IQ distortion is generally not order interchangeable with other distortion such as chromatic dispersion. Therefore, as in the configuration in FIG. 8, when an IQ distortion compensation block is provided by distortion compensation for each block, the order is important.

An example of receiver side equalization digital signal processing for equalizing various pieces of distortion in optical fiber communication, including IQ distortion occurring in a transmitter or receiver, is described in Non Patent Literature 2. FIG. 10 illustrates an adaptive multi-layer filter that performs equalization signal processing. The adaptive multi-layer filter includes, in this order, an in-receiver distortion compensation 701, a chromatic dispersion compensation 702, a polarization demultiplexing 703, a carrier phase compensation 704, and an in-transmitter distortion compensation 705. In the adaptive multi-layer filter, various pieces of distortion being included in the reception signal are compensated for in the reverse order of the occurrence.

The in-receiver distortion compensation 701 includes a WL 2×1 filter for each polarization, i.e., for each of input signals x₁ and x₂. The chromatic dispersion compensation 702 includes an SL filter for each polarization. The polarization demultiplexing 703 includes a 2×2 MIMO SL filter. The carrier phase compensation 704 includes an SL filter for each polarization. The in-transmitter distortion compensation 705 includes a WL 2×1 filter for each polarization.

FIG. 11 illustrates a WL 2×1 filter to be used for the in-receiver distortion compensation 701 and the in-transmitter distortion compensation 705. A WL 2×1 filter 800 includes a complex conjugate calculating unit 801. The complex conjugate calculating unit 801 calculates a complex conjugate of an input complex signal. In the WL 2×1 filter 800, a complex signal is input to a FIR filter 802, and a complex conjugate signal is input to a FIR filter 803. The WL 2×1 filter 800 outputs a signal acquired by adding an output of the FIR filter 802 and an output of the FIR filter 803. The in-receiver distortion compensation 701 and the in-transmitter distortion compensation 705 each have such a WL 2×1 filter 800 for each polarization.

Characteristics of in-transmitter distortion and in-receiver distortion occurring in an optical communication system are usually unknown. Therefore, filter coefficients of the in-receiver distortion compensation 701 and the in-transmitter distortion compensation 705 need to be adaptively controlled. However, as in the configuration in FIG. 8, it is difficult in this case to control the coefficient, based on a direct input and output of each of filter blocks. This is because, in blocks other than the last in-transmitter distortion compensation 705, distortion that is not compensated for remains in the output. This makes it extremely difficult to design a suitable loss function to be minimized for adaptive control.

In FIG. 10, a loss function calculating unit 730 calculates, as a loss function, a difference from a desired state of the filter output of a final layer, i.e., the output of the in-transmitter distortion compensation 705. A coefficient updating unit 710 calculates a gradient for the loss function of all the coefficients of each filter block, based on a fact that the outputs of all the filter blocks can be represented differentially with respect to their inputs and coefficients, and based on an error back propagation method. The coefficient updating unit 710 adaptively controls the coefficient of each filter block in such a way as to minimize the loss function by using the calculated gradient.

A PLL 720 controls a phase rotation amount of the carrier phase compensation 704 according to the output of the in-transmitter distortion compensation 705 being the final layer of the filter block. By using the adaptive multi-layer filter illustrated in FIG. 10, even when a plurality of pieces of distortion including IQ distortion in the transmitter and the receiver are present at the same time, high-accuracy receiver side equalization digital signal processing can be achieved.

### CITATION LIST

### Non Patent Literature

### [Non Patent Literature 1]

S. J. Savory, “Digital filters for coherent optical receivers,” Opt. Express 16(2), 804 (2008).

### [Non Patent Literature 2]

M. Arikawa and K. Hayashi, “Adaptive equalization of transmitter and receiver IQ skew by multi-layer linear and widely linear filters with deep unfolding,” Opt. Express 28(16), 23478 (2020).

### [Non Patent Literature 3]

M. Arikawa and K. Hayashi, “Transmitter and receiver impairment monitoring using adaptive multi-layer linear and widely linear filter coefficients controlled by stochastic gradient descent,” Opt. Express 29(8), 11548 (2021).

### SUMMARY OF INVENTION

### Technical Problem

In the adaptive multi-layer filter illustrated in FIG. 10, which is described in Non Patent Literature 2, various pieces of distortion are compensated for multi-layer FIR filters. With this configuration, due to the convolutional relationship of the FIR filters, the time span of samples involved in calculations is increased as the layers are tracked back further in such a way as to acquire an output of a sample at a single time after the final distortion compensation.

Description is made below on various pieces of distortion compensation processing and a state of coefficient update by the multi-layer filter. An output signal vector and an input signal vector of an 1-th layer relating to acquisition of a sample of an output signal at the time k are represented respectively as follows.

$${u}_{i}^{[ l ]} [ k ] = {( {u}_{i}^{[ l ]} [ k ] , {u}_{i}^{[ l ]} [ k - 1 ] , … , {u}_{i}^{[ l ]} [ k - {M}_{l} + 1 ] )}^{T} \qquad ( 1 )$$

$${u}_{i}^{[ l - 1 ]} [ k ] = {( {u}_{i}^{[ l - 1 ]} [ k ] , {u}_{i}^{[ l - 1 ]} [ k - 1 ] , … , {u}_{i}^{[ l - 1 ]} [ k - {M}_{l - 1} + 1 ] )}^{T} \qquad ( 2 )$$

Herein, M₁ and Mₗ₋₁ represent lengths of the output signal vector and the input signal vector of the l-th layer, respectively. Due to the relationship of the multi-layer filter, the input signal vector of the l-th layer matches with the output signal vector of the 1-1-th layer. i=1, 2 represents polarizations thereof, respectively. When spatial mode compensation is performed in the adaptive multi-layer filter, i is extended to a value greater than 2.

When the filter of the l-th layer is an SL MIMO filter, a filter coefficient hᵢⱼ[1] is represented as follows.

$${h}_{ij}^{[ l ]} = {( {h}_{ij}^{[ l ]} [ 0 ] , {h}_{ij}^{[ l ]} [ 1 ] , … , {h}_{ij}^{[ l ]} [ {M}^{[ l ]} - 1 ] )}^{T} \qquad ( 3 )$$

A tap length M^{[l]} in the filter in the l-th layer is represented as follows due to the convolution relationship.

$${M}^{( l )} = {M}_{l - 1} - {M}_{l} + 1 \qquad ( 4 )$$

When the filter in the l-th layer is an SL MIMO filter, forward direction propagation is represented as follows.

$${u}_{i}^{[ l ]} [ k ] = {\sum }_{j = 1}^{2} {H}_{ij}^{[ l ] *} {u}_{j}^{[ l - 1 ]} [ k ] \qquad ( 5 )$$

Herein, the following expression is given, and Hᵢⱼ[1] is a matrix of size M₁×Mₗ₋₁.

$${H}_{ij}^{[ l ]} = ( \begin{matrix}{h}_{ij}^{[ l ]} [ 0 ] & {h}_{ij}^{[ l ]} [ 1 ] & … & {h}_{ij}^{[ l ]} [ {M}^{[ l ]} - 1 ] & 0 & … & 0 \\ 0 & ⋱ & ⋱ & & ⋱ & ⋱ & ⋮ \\ ⋮ & & & & & & 0 \\ 0 & … & 0 & {h}_{ij}^{[ l ]} [ 0 ] & {h}_{ij}^{[ l ]} [ 1 ] & … & {h}_{ij}^{[ l ]} [ {M}^{[ l ]} - 1 ]\end{matrix} ) \qquad ( 6 )$$

When Expression 5 given above is modified, the following expressions are given.

$${u}_{i}^{[ l ]} [ k ] = {\sum }_{j = 1}^{2} {U}_{j}^{[ l - 1 ]} [ k ] {h}_{ij}^{[ l ] *} \qquad ( 7 )$$

$${U}_{j}^{[ l - 1 ]} [ k ] = ( \begin{matrix}{u}_{j}^{[ l - 1 ]} [ k ] & {u}_{j}^{[ l - 1 ]} [ k - 1 ] & … & {u}_{j}^{[ l - 1 ]} [ k - {M}^{[ l ]} + 1 ] \\ {u}_{j}^{[ l - 1 ]} [ k - 1 ] & {u}_{j}^{[ l - 1 ]} [ k - 2 ] & … & {u}_{j}^{[ l - 1 ]} [ k - {M}^{[ l ]} ] \\ ⋮ & & & ⋮ \\ {u}_{j}^{[ l - 1 ]} [ k - {M}_{l} + 1 ] & {u}_{j}^{[ l - 1 ]} [ k - {M}_{l} ] & … & {u}_{j}^{[ l - 1 ]} [ k - {M}_{l - 1} + 1 ]\end{matrix} ) \qquad ( 8 )$$

Uⱼ^{[l-1]}[k] is a matrix of size M₁×Mₗ₋₁.

As illustrated in Non Patent Literature 2, even when the filter in the l-th layer is an SL filter arranged for each polarization or a WL filter, calculation similar to that given above can be performed. In the multi-layer filter described in Non Patent Literature 2, all the filter coefficients, except for those of the chromatic dispersion compensating filter whose coefficients are operated quasi-statically and the carrier phase compensating filter whose compensation amount is determined by the PLL, are adaptively controlled based on the final output of the multi-layer filter.

For example, when a DALMS algorithm and a stochastic gradient descent method are used for updating the coefficient, the filter coefficient is updated in such a way as to minimize a loss function φ[k]. The loss function φ[k] is represented in the following expression, where an output sample of the multi-layer filter is yᵢ[k], and a training signal is dᵢ[k].

$$ϕ [ k ] = {{\sum }_{i = 1}}^{2} {\vert {d}_{i} [ k ] - {y}_{i} [ k ] \vert}^{2} \qquad ( 9 )$$

Coefficient update for a filter coefficient ξ is represented as follows.

$${ξ}^{*} \to {ξ}^{*} - 2 α \frac{\partial ϕ}{\partial ξ} \qquad ( 10 )$$

α represents a step size for determining magnitude of coefficient update. A gradient of the loss function is determined sequentially from the final layer, by using an error back propagation method. In a case of a DALMS algorithm, the gradient of the loss function for the output of the final layer is represented as follows.

$$\frac{\partial ϕ}{\partial {y}_{i} [ k ]} = - {e}_{i}^{*} \qquad ( 11 )$$

$$\frac{\partial ϕ}{\partial {y}_{i}^{*} [ k ]} = - {e}_{i} \qquad ( 12 )$$

In a case in which the filter in the l-th layer is an SL MIMO filter, when the gradient is given for the output vector of the filter in the l-th layer, the gradient for the input vector and the coefficient is represented as follows due to backward direction propagation.

$$\frac{\partial ϕ}{\partial {h}_{ij}^{[ l ]} [ k ]} = {U}_{j}^{[ l - 1 ] †} [ k ] \frac{\partial ϕ}{\partial {u}_{i}^{[ l ] *} [ k ]} \qquad ( 13 )$$

$$\frac{δ ϕ}{\partial {u}_{j}^{[ l - 1 ]} [ k ]} = {\sum }_{i = 1}^{2} {H}_{i j}^{[ l ] †} \frac{δ ϕ}{δ {u}_{i}^{[ l ]} [ k ]} \qquad ( 14 )$$

$$\frac{δϕ}{\partial {u}_{j}^{[ l - 1 ] *} [ k ]} = {\sum }_{i = 1}^{2} {H}_{ij}^{[ l ] T} \frac{δ ϕ}{\partial {u}_{i}^{[ l ] *} [ k ]} \qquad ( 15 )$$

Further, the loss function to be minimized is a real number, and such a case is represented as follows.

$$\frac{δ ϕ}{\partial {u}_{j}^{[ l ] *} [ k ]} = {( \frac{δϕ}{\partial {u}_{j}^{[ l ]} [ k ]} )}^{*} \qquad ( 16 )$$

When the filter of the l-th layer is an SL filter for each polarization or a WL filter, calculation can be performed similarly. In this manner, distortion compensation processing by the multi-layer filter is performed, and the filter coefficients are adaptively updated based on the final output signal sample.

As represented in Expressions 13 to 15, in error back propagation of the multi-layer filter, an arithmetic operation of a matrix such as Uⱼ^{[l-1]}[k] and Hᵢⱼ is required in each layer. A size of the matrix depends on the lengths of the input vector and the output vector in each layer. Meanwhile, Expression 4 holds with regard to the lengths of the input vector and the output vector in each layer, and hence, in the multi-layer filter, M₁ and Mₗ₋₁ tend to be greater values in a layer closer to the initial stage. This is particularly pronounced when a large filter having a tap length M[l] is present in the multi-layer filter.

For example, in ultra-long distance single-mode fiber transmission for 10,000 km, accumulated chromatic dispersion reaches approximately 170 ns/nm. When chromatic dispersion compensation in the time domain with double oversampling is performed for a typical 32-Gbaud symbol rate signal, the required tap length exceeds 5,500. In this case, various pieces of distortion are compensated for with the configuration illustrated in FIG. 10, the input vectors and the output vectors in the first layer and the second layer, and the size of the matrix such as Uⱼ^{[l-1]}[k] and Hᵢⱼ[1] is increased, and a calculation amount required for error back propagation is increased. As described above, when distortion compensation processing by the multi-layer filter as illustrated in FIG. 10 is applied to ultra-long distance single-mode fiber transmission, there arises a problem of an enormous calculation amount for coefficient update.

In view of the above-described circumstance, an object of the present disclosure is to provide a communication system, a receiver, an equalization signal processing circuit, and an equalization signal processing method that are capable of compensating for various pieces of distortion while preventing increase in calculation amount.

### Solution to Problem

In order to achieve the above object, according to a first aspect of the present disclosure, there is provided an equalization signal processing circuit. The equalization signal processing circuit includes: a first filter configured to perform compensation for first distortion being included in a reception signal being acquired by coherent-receiving a signal being transmitted from a transmitter via a transmission path, with respect to the reception signal and a complex conjugate signal of the reception signal, and output the reception signal and the complex conjugate signal being subjected to compensation for the first distortion; a filter group including a second filter configured to receive, as input signals, the reception signal and the complex conjugate signal being subjected to compensation for the first distortion, perform compensation for second distortion being included in the reception signal, and output the reception signal being subjected to compensation for the second distortion; and a coefficient updating means for adaptively controlling a filter coefficient of the second filter, based on a difference between an output signal being output from the filter group and a predetermined value of the output signal

According to a second aspect of the present disclosure, there is provided a receiver. The receiver includes: a receiving circuit configured to coherent-receive a signal being transmitted from a transmitter via a transmission path; and an equalization signal processing circuit configured to perform equalization signal processing with respect to the reception signal being coherent-received. The equalization signal processing circuit includes: a first filter configured to perform compensation for first distortion being included in the reception signal with respect to the reception signal and a complex conjugate signal of the reception signal, and output the reception signal and the complex conjugate signal being subjected to compensation for the first distortion; a filter group including a second filter configured to receive, as input signals, the reception signal and the complex conjugate signal being subjected to compensation for the first distortion, perform compensation for second distortion being included in the reception signal, and output the reception signal being subjected to compensation for the second distortion; and a coefficient updating means for adaptively controlling a filter coefficient of the second filter, based on a difference between an output signal being output from the filter group and a predetermined value of the output signal.

According to a third aspect of the present disclosure, there is provided a communication system. The communication system includes: a transmitter configured to transmit a signal via a transmission path; and a receiver configured to receive the signal being transmitted. The receiver includes: a receiving circuit configured to coherent-receive a signal being transmitted from the transmitter; and an equalization signal processing circuit configured to perform equalization signal processing with respect to the reception signal being coherent-received. The equalization signal processing circuit includes: a first filter configured to perform compensation for first distortion being included in the reception signal with respect to the reception signal and a complex conjugate signal of the reception signal, and output the reception signal and the complex conjugate signal being subjected to compensation for the first distortion; a filter group including a second filter configured to receive, as input signals, the reception signal and the complex conjugate signal being subjected to compensation for the first distortion, perform compensation for second distortion being included in the reception signal, and output the reception signal being subjected to compensation for the second distortion; and a coefficient updating means for adaptively controlling a filter coefficient of the second filter, based on a difference between an output signal being output from the filter group and a predetermined value of the output signal.

According to a fourth aspect of the present disclosure, there is provided an equalization signal processing method. The equalization signal processing method includes: performing compensation for first distortion being included in a reception signal being acquired by coherent-receiving a signal being transmitted from a transmitter via a transmission path, with respect to the reception signal and a complex conjugate signal of the reception signal, by using a first filter; inputting, to a filter group including a second filter, the reception signal and the complex conjugate signal being subjected to compensation for the first distortion, and performing compensation for second distortion being included in the reception signal, by using the second filter; and adaptively controlling a filter coefficient of the second filter, based on a difference between an output signal being output from the filter group and a predetermined value of the output signal.

According to a fifth aspect of the present disclosure, there is provided a computer readable medium. The computer readable medium stores a program for causing a processor to execute processing including: performing compensation for first distortion being included in a reception signal being acquired by coherent-receiving a signal being transmitted from a transmitter via a transmission path, with respect to the reception signal and a complex conjugate signal of the reception signal, by using a first filter; inputting, to a filter group including a second filter, the reception signal and the complex conjugate signal being subjected to compensation for the first distortion, and performing compensation for second distortion being included in the reception signal, by using the second filter; and adaptively controlling a filter coefficient of the second filter, based on a difference between an output signal being output from the filter group and a predetermined value of the output signal.

### Advantageous Effects of Invention

The communication system, the receiver, the equalization signal processing circuit, the equalization signal processing method, and the computer readable medium according to the present disclosure are capable of compensating for various pieces of distortion while preventing increase in calculation amount.

### BRIEF DESCRIPTION OF DRAWINGS

FIG. 1 is a block diagram schematically illustrating a communication system according to the present disclosure;

FIG. 2 is a block diagram illustrating a schematic configuration of a receiver;

FIG. 3 is a block diagram illustrating a signal transmission system according to one example embodiment of the present disclosure;

FIG. 4 is a block diagram illustrating an example of digital signal processing in an equalizing unit;

FIG. 5 is a block diagram illustrating a 2×1 SL MISO filter;

FIG. 6 is a graph illustrating a simulation result;

FIG. 7 is a block diagram illustrating a configuration example of the equalizing unit;

FIG. 8 is a block diagram illustrating an example of receiver side equalization digital signal processing described in Non Patent Literature 1;

FIG. 9 is a block diagram illustrating a 2×2 MIMO filter;

FIG. 10 is a block diagram illustrating an adaptive multi-layer filter for performing equalization signal processing; and

FIG. 11 is a block diagram illustrating a WL 2×1 filter.

### EXAMPLE EMBODIMENT

Prior to description of an example embodiment of the present disclosure, an outline of the present disclosure will be described. FIG. 1 schematically illustrates a communication system according to the present disclosure. A communication system 10 includes a transmitter 11 and a receiver 15. The transmitter 11 and the receiver 15 are connected to each other via a transmission path 13. The transmitter 11 transmits a signal via the transmission path 13. The receiver 15 receives a signal transmitted from the transmitter 11 via the transmission path 13.

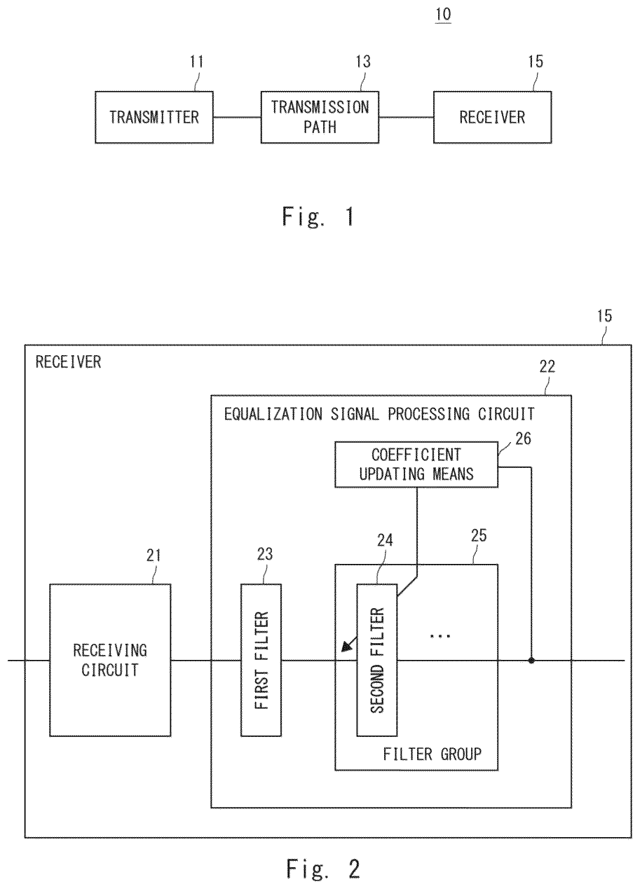

FIG. 2 illustrates a schematic configuration of the receiver 15. The receiver 15 includes a receiving circuit 21 and an equalization signal processing circuit 22. The receiving circuit 21 coherent-receives a signal transmitted from the transmitter 11. The equalization signal processing circuit 22 performs equalization signal processing on the reception signal being coherent-received.

The equalization signal processing circuit 22 includes a first filter 23, a filter group 25, and a coefficient updating means 26. The first filter 23 performs compensation for first distortion being included in a reception signal being coherent-received, with respect to the reception signal and a complex conjugate signal of the reception signal, and outputs the reception signal and the complex conjugate signal being subjected to compensation for the first distortion.

The filter group 25 includes a second filter 24. The second filter 24 receives, as input signals, the reception signal and the complex conjugate signal being subjected to compensation for the first distortion, and performs compensation for second distortion being included in the reception signal. The filter group 25 may include one or more filters being connected in series along a signal path of the reception signal, on a downstream side with respect to the second filter 24. The coefficient updating means 26 adaptively controls a filter coefficient of the second filter 24, based on a difference between an output signal being output from the filter group 25 and a predetermined value of the output signal.

In the present disclosure, the first filter 23 that performs compensation for the first distortion is arranged on the upstream side with respect to the second filter 24 that performs compensation for the second distortion. It is assumed that the second distortion is distortion that is generally compensated for by using a WL filter. Hypothetically, when the first filter 23 is arranged on the downstream side with respect to the second filter 24 in the filter group 25, it is required to calculate the gradient of the loss function with respect to the input vector and the coefficient of the first filter 23 for updating the filter coefficient of the second filter 24. In this case, when the tap length of the first filter 23 is large, a calculation amount for coefficient update is increased. In the present disclosure, as described later, while the first filter 23 is arranged before the second filter 24, the second filter 24 can perform compensation for the second distortion. Thus, the equalization signal processing circuit 22 can perform compensation for various pieces of distortion while preventing increase in calculation amount for coefficient update.

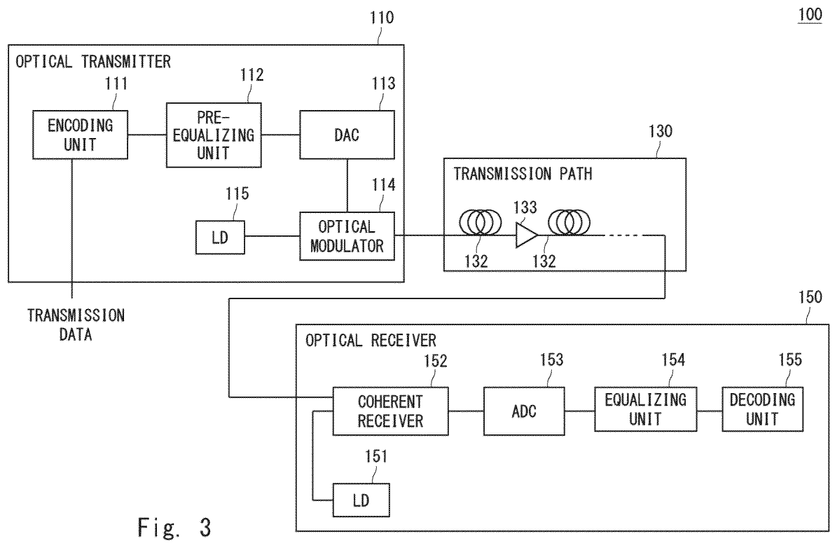

Hereinafter, an example embodiment of the present disclosure will be described in detail with reference to the drawings. FIG. 3 illustrates a signal transmission system according to one example embodiment of the present disclosure. In the present example embodiment, it is assumed that the signal transmission system is an optical fiber communication system that adopts a polarization multiplexing QAM system and performs coherent reception. An optical fiber communication system 100 includes an optical transmitter 110, a transmission path 130, and an optical receiver 150. The optical fiber communication system 100 constitutes, for example, an optical submarine cable system. The optical fiber communication system 100 is associated with the communication system 10 illustrated in FIG. 1. The optical transmitter 110 is associated with the transmitter 11 illustrated in FIG. 1. The transmission path 130 is associated with the transmission path 13 illustrated in FIG. 1. The optical receiver 150 is associated with the receiver 15 illustrated in FIG. 1.

The optical transmitter 110 converts a transmission data into a polarization multiplexed optical signal. The optical transmitter 110 includes an encoding unit 111, a pre-equalizing unit 112, a digital analog converter (DAC) 113, an optical modulator 114, and a laser diode (LD) 115. The encoding unit 111 encodes a transmission data and generates a signal sequence for optical modulation. In a case of the polarization multiplexing QAM system, the encoding unit 111 generates a total of four series of signals being an in-phase (I) component and a quadrature (Q) component of each of X polarization (first polarization) and Y polarization (second polarization). Note that, in FIG. 3, for the sake of simplification of the drawing, encoded four-series signals are illustrated as one solid line. Hereinafter, one solid line illustrated in FIG. 3 collectively represents signal series having a predetermined number, as a physical entity

The pre-equalizing unit 112 performs pre-equalization for compensating for distortion or the like of a device in the optical transmitter in advance for the encoded four-series signal. The DAC 113 converts each of the four-series signals being performed the pre-equalization into an analog electric signal.

The LD 115 outputs continuous wave (CW) light. The optical modulator 114 modulates the CW light output from the LD 115 in response to the four-series signals output from the DAC 113, and generates an optical signal of polarization multiplexing QAM. The optical signal (polarization multiplexed optical signal) generated by the optical modulator 114 is output to the transmission path 130.

The transmission path 130 transmits the polarization multiplexed optical signal output from the optical transmitter 110 to the optical receiver 150. The transmission path 130 includes an optical fiber 132 and an optical amplifier 133. The optical fiber 132 guides an optical signal transmitted from the optical transmitter 110. The optical amplifier 133 amplifies an optical signal, and compensates for a propagation loss in the optical fiber 132. The optical amplifier 133 is configured, for example, as an erbium doped fiber amplifier (EDFA). The transmission path 130 may include a plurality of optical amplifiers 133.

The optical receiver 150 includes an LD 151, a coherent receiver 152, an analog digital converter (ADC) 153, an equalizing unit 154, and a decoding unit 155. In the optical receiver 150, circuits such as the equalizing unit (equalizer) 154 and the decoding unit (decoder) 155 may be configured by using a device such as a digital signal processor (DSP), for example.

The LD 151 outputs CW light as local oscillator light. In the present example embodiment, the coherent receiver 152 is configured as a polarization diversity type coherent receiver. The coherent receiver 152 performs coherent detection on an optical signal transmitted through the optical fiber 132, by using the CW light output from the LD 151. The coherent receiver 152 outputs four-series reception signals (electric signals) being equivalent to the I component and Q component of the X polarization and Y polarization being performed coherent detection. The coherent receiver 152 is associated with the receiving circuit 21 illustrated in FIG. 2.

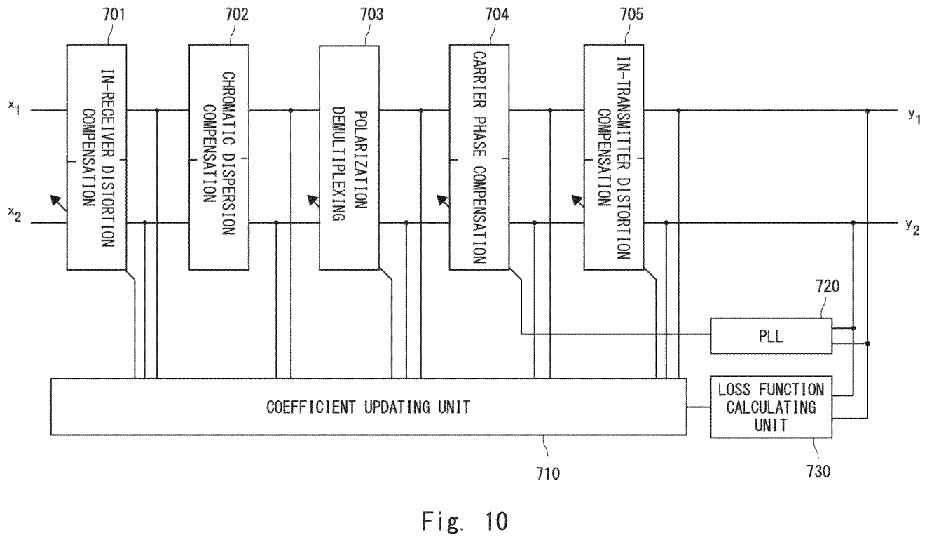

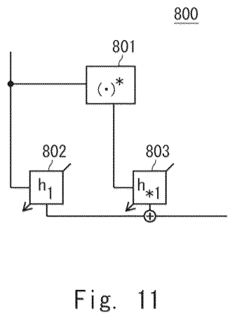

The ADC 153 samples the reception signal output from the coherent receiver 152, and converts the reception signal into a signal in a digital domain. The equalizing unit 154 performs receiver side equalization signal processing on the four-series reception signals being sampled by the ADC 153. The equalizing unit 154 performs equalization signal processing on the reception signal, and thereby compensates for various pieces of distortion in the optical fiber communication system. Hereinafter, it is assumed that, similarly to the example of FIG. 10, the equalizing unit 154 performs in-receiver distortion compensation, chromatic dispersion compensation, polarization demultiplexing, carrier phase compensation, and in-transmitter distortion compensation. The equalizing unit 154 is associated with the equalization signal processing circuit 22 illustrated in FIG. 2. The decoding unit 155 decodes the signal being performed the equalization signal processing by the equalizing unit 154, and restores the transmitted data. The decoding unit 155 outputs the restored data to not-illustrated another circuit

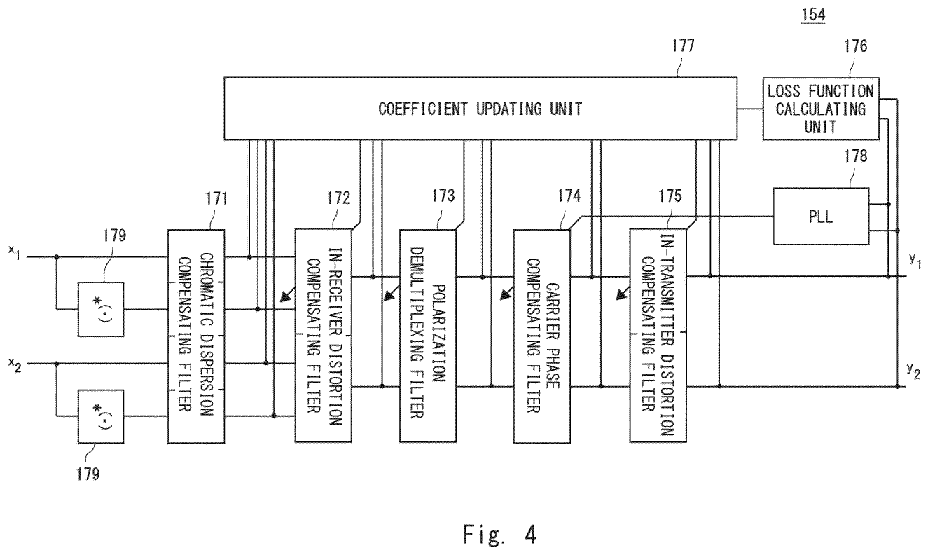

FIG. 4 illustrates a specific example of digital signal processing (equalization signal processing) in the equalizing unit 154. In the example illustrated in FIG. 4, the digital signal processing includes a chromatic dispersion compensating filter 171, an in-receiver distortion compensating filter 172, a polarization demultiplexing filter 173, a carrier phase compensating filter 174, an in-transmitter distortion compensating filter 175, a loss function calculating unit 176, a coefficient updating unit 177, and a PLL 178. The digital signal processing configures the equalization signal processing circuit that performs an equalization signal processing method according to the present example embodiment. In the present example embodiment, the in-receiver distortion compensating filter 172, the polarization demultiplexing filter 173, the carrier phase compensating filter 174, and the in-transmitter distortion compensating filter 175 constitute a multi-layer filter whose coefficients are adaptively controlled.

Two reception complex signals (x₁ and x₂) associated with two polarizations are input to the equalizing unit 154. The reception complex signal being input to the equalizing unit 154 may be a signal in which known device distortion is compensated for in advance. Further, the reception complex signal being input to the equalizing unit 154 may be a signal subjected to matching filter. A complex conjugate calculating unit 179 calculates complex conjugate (x₁* and x₂*) of the two reception complex signals (x₁ and x₂). The two reception complex signals (x₁ and x₂) and the complex conjugate signals (x₁* and x₂*) are input to the chromatic dispersion compensating filter 171.

The chromatic dispersion compensating filter 171 performs compensation for distortion (first distortion) caused by chromatic dispersion in the transmission path, with respect to each of the signals (x₁, x₂, x₁*, and x₂*) being input. In other words, the chromatic dispersion compensating filter 171 performs filter processing for compensating for chromatic dispersion with respect to each of the signals (x₁, x₂, x₁*, and x₂*) being input. The chromatic dispersion compensating filter 171 includes a complex signal input complex coefficient filter having a predetermined tap length. Any one of a time domain filter and a frequency domain filter may be used for the chromatic dispersion compensating filter 171. The coefficient of the chromatic dispersion compensating filter 171 is determined in such a way as to compensate for accumulated chromatic dispersion according to transmission path information such as a transmission fiber and a transmission distance, as is typically performed in optical fiber communication. The coefficient of the chromatic dispersion compensating filter 171 is statically handled. The chromatic dispersion compensating filter 171 is associated with the first filter 23 illustrated in FIG. 2.

A signal being acquired by performing chromatic dispersion compensation with respect to the reception complex signal for each polarization and a signal being acquired by performing chromatic dispersion compensation with respect to the complex conjugate of the reception complex signal for each polarization, which are output from the chromatic dispersion compensating filter 171, are input to the multi-layer filter. The multi-layer filter includes the in-receiver distortion compensating filter 172, the polarization demultiplexing filter 173, the carrier phase compensating filter 174, and the in-transmitter distortion compensating filter 175 in the stated order from the signal input side. The multi-layer filter is associated with the filter group 25 illustrated in FIG. 2. The in-receiver distortion compensating filter 172 is associated with the second filter 24 illustrated in FIG. 2.

The distortion compensating filter 172 compensates for signal distortion (second distortion) occurring in the optical receiver 150 (FIG. 3). The polarization demultiplexing filter 173 compensates for signal distortion caused by a polarization state variation and polarization mode dispersion during optical fiber transmission. The carrier phase compensating filter 174 compensates for signal distortion caused by the frequency offset and the phase offset between the carrier of the transmitted optical signal and the local oscillator light on the receiving side. The in-transmitter distortion compensating filter 175 (third filter) compensates for signal distortion (third distortion) occurring in the optical transmitter 110. Signals y₁ and y₂ that are output from the in-transmitter distortion compensating filter 175 are signals in which various pieces of distortion included in the reception complex signals x₁ and x₂ are compensated for.

In FIG. 4, the filter of each of the blocks is configured according to characteristics of distortion to be compensated for. For example, the filter of each of the blocks is configured by using a FIR filter. In the filter of the each of the blocks, a tap length of the FIR filter is set to a tab length according to characteristics of distortion to be compensated for.

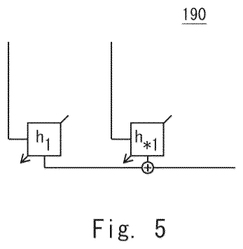

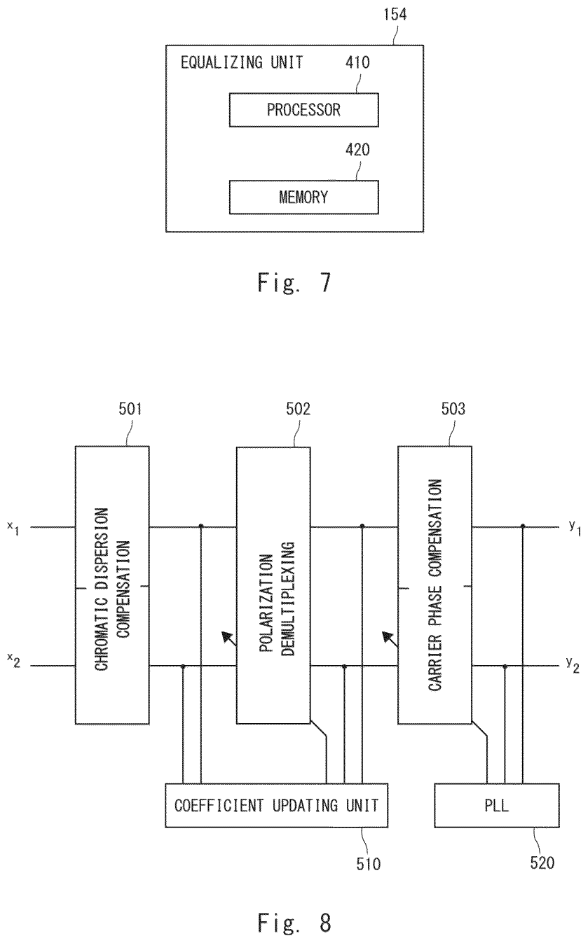

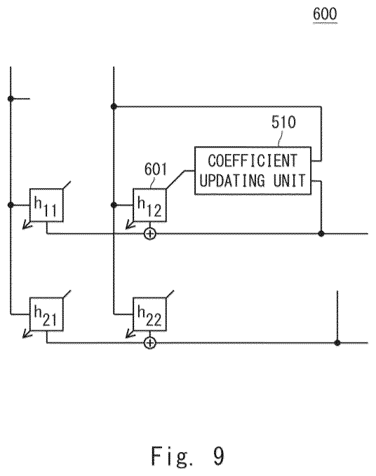

The in-receiver distortion compensating filter 172 includes two 2×1 SL multi-input single-output (MISO) filters being arranged respectively for polarizations. FIG. 5 illustrates a 2×1 SL MISO filter. In FIG. 5, a MISO filter 190 includes two FIR filters 191 and 192. The FIR filter 191 convolves a complex coefficient (first complex coefficient) h₁ with respect to the complex signal being subjected to chromatic dispersion compensation. Further, the FIR filter 192 convolves a complex coefficient (second complex coefficient) h*₁ with respect to the complex signal being subjected to chromatic dispersion compensation. The MISO filter 190 outputs a signal being acquired by adding the output of the FIR filter 191 and the output of the FIR filter 192. The in-receiver distortion compensating filter 172 includes the MISO filter 190 illustrated in FIG. 7 for each of a pair (x₁, x₁*) of the complex signal of the X polarization and the complex conjugate signal and a pair (x₂, x₂*) of the complex signal of the Y polarization and the complex conjugate signal. The in-receiver distortion compensating filter 172 outputs the signal being acquired by adding the output of the FIR filter 191 and the output of the FIR filter 192, for each polarization.

Note that description is made above on the example in which the in-receiver distortion compensating filter 172 includes the two 2×1 SL MISO filters arranged respectively for polarizations, but the present example embodiment is not limited thereto. For example, depending on the configuration of the receiver, distortion caused by signal mixing between polarizations may be prominently manifested. In such a case, the in-receiver distortion compensating filter 172 may use a 4×2 SL MIMO filter in place of the two 2×1 SL MISO filters.

The output signals associated with the two polarizations, which are output from the in-receiver distortion compensating filter 172, are input to the polarization demultiplexing filter 173. The polarization demultiplexing filter 173 includes a 2×2 MIMO SL filter. The output signals associated with the two polarizations, which are output from the polarization demultiplexing filter 173, are input to the carrier phase compensating filter 174. The carrier phase compensating filter 174 includes an SL filter of one tap, which is arranged for each polarization. The output signals associated with the two polarizations, which are output from the carrier phase compensating filter 174, are input to the in-transmitter distortion compensating filter 175. The in-transmitter distortion compensating filter 175 includes a WL 2×1 filter arranged for each polarization.

The coefficient of the carrier phase compensating filter 174, in other words, a compensation amount in carrier phase compensation is controlled by the PLL 178. The PLL 178 determines a compensation amount in carrier phase compensation, based on the output of the in-transmitter distortion compensating filter 175, which is the final output of the multi-layer filter.

The loss function calculating unit 176 calculates, as a loss function, a difference between the output from the in-transmitter distortion compensating filter 175 being the final stage of the multi-layer filter and a desired state. The coefficient updating unit 177 updates the coefficients of the in-receiver distortion compensating filter 172, the polarization demultiplexing filter 173, and the in-transmitter distortion compensating filter 175. For example, the coefficient updating unit 177 updates the coefficient of the each of the filters for each sample at a single time or a symbol. For example, the coefficient updating unit 177 successively updates the coefficient of each of the filters by using an error back propagation method and a gradient descent method in such a way as to minimize the loss function. For example, the coefficient updating unit 177 updates the filter coefficient of each of the filters by using a DALMS algorithm and a stochastic gradient descent method. The coefficient updating unit 177 is associated with the coefficient updating means 26 illustrated in FIG. 2.

Next, an operation principle of equalization signal processing illustrated in FIG. 4 is described. In general, in a case in which a WL filter and an SL filter are applied to a signal, when the order thereof is switched, the result before switching is different from that after switching. Therefore, in the adoptive multi-layer filter illustrated in FIG. 10 that compensates for distortion in the order in which distortion occurs and the reverse order, the in-receiver distortion compensation 701 and the chromatic dispersion compensation 702 cannot simply be switched.

However, according to the distributive property of multiplication, the equivalence described below holds. Herein, a case in which a 2×1 WL filter is first applied to the input signal x, and then chromatic dispersion compensation (SL filter) is applied thereto is considered. An output signal y(t) of the 2×1 WL filter with respect to the input signal x is represented in the expression given below.

$$y ( t ) = \int {h}_{1} ( τ ) * x ( t - τ ) d τ + \int {h}_{*}^{*} ( τ ) x * ( t - τ ) d τ \qquad ( 17 )$$

Further, an output signal z(t) that is acquired by applying chromatic dispersion compensation filter h_{CD} to the output signal y(t) of the 2×1 WL filter is represented as follows.

$$z ( t ) = \int {h}_{CD}^{*} ( τ ) y ( t - τ ) d τ \qquad ( 18 )$$

When the distributive property of multiplication is used, Expression 18 given above can be rewritten as Expression 19 given below.

$$z ( t ) = \int {h}_{CD}^{*} ( τ ) + {h}_{1}^{*} ( {τ}^{′} ) x ( t - τ - {τ}^{′} ) d τ d {τ}^{′} + \int {h}_{CD}^{*} ( τ ) {h}_{* 1}^{*} ( {τ}^{′} ) x * ( t - τ - {τ}^{′} ) d τ d {τ}^{′} \qquad ( 19 )$$

When Expression 19 given above is rearranged, Expression 20 given below is acquired.

$$z ( t ) = \int {h}_{1}^{*} ( {τ}^{′} ) ( \int {h}_{CD}^{*} ( τ ) x ( t - {τ}^{′} - τ ) d τ ) d {τ}^{′} + \int {h}_{* 1}^{*} ( {τ}^{′} ) ( \int {h}_{CD}^{*} ( τ ) x * ( t - {τ}^{′} - τ ) d τ ) d {τ}^{′} \qquad ( 20 )$$

As understood from Expression 20 given above, application of the 2×1 WL filter for in-receiver distortion compensation and the SL filter for chromatic dispersion compensation to the input signal in the stated order is equivalent to application of the 2×1 SL MISO filter to the signal acquired by applying chromatic dispersion compensation to the input signal and the signal acquired by applying chromatic dispersion compensation to the complex conjugate signal of the input signal. Therefore, in the digital signal processing illustrated in FIG. 4, in-receiver distortion compensation and chromatic dispersion compensation can be performed suitably. For error back propagation for coefficient update, the expressions for the existing SL MIMO filter can be directly used.

In single-mode fiber long-distance transmission, chromatic dispersion is characterized by a broad time spread, and the number of taps required in the chromatic dispersion compensation filter becomes enormous in such a way as to compensate for such chromatic dispersion. In the digital signal processing illustrated in FIG. 4, the chromatic dispersion compensating filter 171 is independent from the multi-layer filter whose coefficients are adaptively controlled. The multi-layer filter does not include a filter with the large number of taps like a chromatic dispersion compensation filter. Therefore, in the present example embodiment, multiplication of a large-size matrix required for error back propagation for coefficient update can be avoided, and a calculation amount for coefficient update can be significantly reduced.

Further, as described above, the coefficients h₁ and h*₁ of the 2×1 SL MISO filter for in-receiver distortion compensation in the digital signal processing illustrated in FIG. 4 are equivalent to the coefficients h₁ and h*₁ of the 2×1 WL filter for in-receiver distortion compensation in the equalization signal processing illustrated in FIG. 10. Therefore, the digital signal processing in the present example embodiment can be directly applied to detection of a distortion amount, which is described in Non Patent Literature 3.

The inventor performed a simulation to verify the performance of distortion compensation in the configuration of the present example embodiment. In the simulation, a 32-Gbaud polarization-multiplexed probabilistic constellation shaped 64-QAM signal (with an entropy of 2.8 bits/symbol/polarization) is used. This signal is subjected to accumulated chromatic dispersion equivalent to 10,000 km of single-mode fiber transmission and random polarization rotation. Further, in the simulation, it is assumed that the laser phase noise at the transmitter and the receiver is 100 kHz and no non-linear distortion is present, and distortion compensation is performed by the digital signal processing illustrated in FIG. 4, under the condition of a reception optical signal to noise ratio (OSNR) of 30 dB/0.1 nm.

In the simulation, IQ skew 10 ps is given to X-polarization signals in the transmitter and the receiver, and performance of distortion compensation therefor is evaluated. For each filter in a multi-layer filter, T/2-spaced FIR filter is used. Chromatic dispersion is performed in the frequency domain. A known pilot signal with the same format as a transmission signal is inserted into the transmission signal for every 15 symbols, and coefficient update is performed by DALMS using the transmission signal.

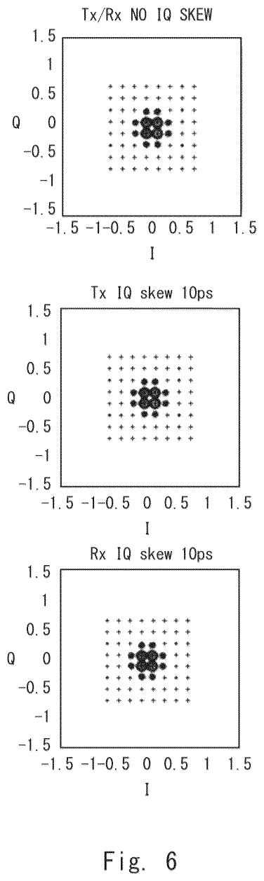

FIG. 6 illustrates the simulation result. In FIG. 7, the simulation result is represented as a constellation diagram acquired by mapping the demodulated signals of the multi-layer filter at a symbol timing on an IQ plane. FIG. 6 illustrates a constellation after compensation in a case in which IQ skew is not given in a transmitter (Tx) and a receiver (Rx), a constellation after compensation in a case in which the IQ skew is given in the transmitter, and a constellation after compensation in a case in which the IQ skew is given in the receiver. Based on the comparison of the three constellations illustrated in FIG. 6, it is understood that similar reception characteristics are acquired in the case in which the IQ skew is given to the transmitter and the receiver and the case in which the IQ skew is not given. Therefore, it is confirmed, from the simulation, that in-transmitter distortion compensation and in-receiver distortion compensation functioned suitably even with the presence of accumulated chromatic dispersion equivalent to 10,000 km of single-mode fiber transmission.

Note that, in the example embodiments described above, the equalizing unit 154 may be configured as a freely selected digital signal processing circuit. FIG. 7 illustrates a configuration example of the equalizing unit 154. For example, the equalizing unit 154 includes one or more processors 410 and one or more memories 420. The processor 410 reads a program being stored in the memory 420, and thereby performs receiver side equalization digital signal processing.

The above program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a random-access memory (RAM), a read-only memory (ROM), a flash memory, a solid-state drive (SSD) or other types of memory technologies, a compact disc (CD), a digital versatile disc (DVD), a Blu-ray disc or other types of optical disc storage, and magnetic cassettes, magnetic tape, magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

While the example embodiments of the present disclosure have been explained in detail above, the present disclosure is not limited to the above-described example embodiments, and changes and modifications to the above-described example embodiments without departing from the spirit of the present disclosure are also included in the present disclosure.

For example, some or all of the above-described example embodiments may be described as follows, but are not limited thereto.

### Supplementary Note 1

An equalization signal processing circuit including:
a first filter configured to perform compensation for first distortion being included in a reception signal being acquired by coherent-receiving a signal being transmitted from a transmitter via a transmission path, with respect to the reception signal and a complex conjugate signal of the reception signal, and output the reception signal and the complex conjugate signal that are subjected to compensation for the first distortion;
a filter group including a second filter configured to receive, as input signals, the reception signal and the complex conjugate signal that are subjected to compensation for the first distortion, perform compensation for second distortion being included in the reception signal, and output the reception signal being subjected to compensation for the second distortion; and
a coefficient updating means for adaptively controlling a filter coefficient of the second filter, based on a difference between an output signal being output from the filter group and a predetermined value of the output signal.

### Supplementary Note 2

The equalization signal processing circuit according to Supplementary note 1, wherein the first distortion includes distortion caused by chromatic dispersion in the transmission path, and the first filter compensates for chromatic dispersion.

### Supplementary Note 3

The equalization signal processing circuit according to Supplementary note 1 or 2, wherein the second distortion includes in-receiver distortion occurring in a receiver, and the second filter compensates for in-receiver distortion.

### Supplementary Note 4

The equalization signal processing circuit according to any one of Supplementary notes 1 to 3, wherein the first filter includes a complex signal input complex coefficient filter having a predetermined tap length, and the second filter includes a multiple input single output (MISO) filter.

### Supplementary Note 5

The equalization signal processing circuit according to Supplementary note 4, wherein the MISO filter convolves a first complex coefficient with respect to the reception signal being subjected to compensation for the first distortion, convolves a second complex coefficient with respect to the complex conjugate signal being subjected to compensation for the first distortion, and adds and outputs the reception signal being convolved with the first complex coefficient and the complex conjugate signal being convolved with the second complex coefficient.

### Supplementary Note 6

The equalization signal processing circuit according to any one of Supplementary notes 1 to 5, wherein the signal being transmitted from the transmitter is a polarization multiplexed signal, and the first filter and the second filter are arranged for each polarization.

### Supplementary Note 7

The equalization signal processing circuit according to any one of Supplementary notes 1 to 6, wherein
the filter group includes one or more filters being connected in series along a signal path of the reception signal, on a downstream side with respect to the second filter, and
the coefficient updating means adaptively control the filter coefficient of the second filter by using an error back propagation method.

### Supplementary Note 8

The equalization signal processing circuit according to Supplementary note 7, wherein
the one or more filters include a third filter configured to perform compensation for third distortion being included in the reception signal, and
the coefficient updating means further adaptively control a filter coefficient of the third filter, based on a difference between an output signal being output from the filter group and a predetermined value of the output signal.

### Supplementary Note 9

The equalization signal processing circuit according to Supplementary note 8, wherein the third distortion includes in-transmitter distortion occurring in a transmitter, and the third filter compensates for in-transmitter distortion.

### Supplementary Note 10

A receiver including:
a receiving circuit configured to coherent-receive a signal being transmitted from a transmitter via a transmission path; and
an equalization signal processing circuit configured to perform equalization signal processing with respect to the reception signal being coherent-received, wherein
the equalization signal processing circuit includes:
   a first filter configured to perform compensation for first distortion being included in the reception signal with respect to the reception signal and a complex conjugate signal of the reception signal, and output the reception signal and the complex conjugate signal that are subjected to compensation for the first distortion;
   a filter group including a second filter configured to receive, as input signals, the reception signal and the complex conjugate signal that are subjected to compensation for the first distortion, perform compensation for second distortion being included in the reception signal, and output the reception signal being subjected to compensation for the second distortion; and
   a coefficient updating means for adaptively controlling a filter coefficient of the second filter, based on a difference between an output signal being output from the filter group and a predetermined value of the output signal.

### Supplementary Note 11

The receiver according to Supplementary note 10, wherein the first distortion includes distortion caused by chromatic dispersion in the transmission path, and the first filter compensates for chromatic dispersion.

### Supplementary Note 12

The receiver according to Supplementary note 10 or 11, wherein the second distortion includes in-receiver distortion occurring in a receiver, and the second filter compensates for in-receiver distortion.

### Supplementary Note 13

The receiver according to any one of Supplementary notes 10 to 12, wherein the first filter includes a complex signal input complex coefficient filter having a predetermined tap length, and the second filter includes a multiple input single output (MISO) filter.

### Supplementary Note 14

A communication system including:
a transmitter configured to transmit a signal via a transmission path; and
a receiver configured to receive the signal being transmitted, wherein
the receiver includes:
   a receiving circuit configured to coherent-receive a signal being transmitted from the transmitter; and
   an equalization signal processing circuit configured to perform equalization signal processing with respect to the reception signal being coherent-received, and
the equalization signal processing circuit includes:
   a first filter configured to perform compensation for first distortion being included in the reception signal with respect to the reception signal and a complex conjugate signal of the reception signal, and output the reception signal and the complex conjugate signal that are subjected to compensation for the first distortion;
   a filter group including a second filter configured to receive, as input signals, the reception signal and the complex conjugate signal that are subjected to compensation for the first distortion, perform compensation for second distortion being included in the reception signal, and output the reception signal being subjected to compensation for the second distortion; and
   a coefficient updating means for adaptively controlling a filter coefficient of the second filter, based on a difference between an output signal being output from the filter group and a predetermined value of the output signal.

### Supplementary Note 15

The communication system according to Supplementary note 14, wherein the first distortion includes distortion caused by chromatic dispersion in the transmission path, and the first filter compensates for chromatic dispersion.

### Supplementary Note 16

The communication system according to Supplementary note 14 or 15, wherein the second distortion includes in-receiver distortion occurring in a receiver, and the second filter compensates for in-receiver distortion.

### Supplementary Note 17

An equalization signal processing method including:
performing compensation for first distortion being included in a reception signal being acquired by coherent-receiving a signal being transmitted from a transmitter via a transmission path, with respect to the reception signal and a complex conjugate signal of the reception signal, by using a first filter;
inputting, to a filter group including a second filter, the reception signal and the complex conjugate signal that are subjected to compensation for the first distortion, and performing compensation for second distortion being included in the reception signal, by using the second filter; and
adaptively controlling a filter coefficient of the second filter, based on a difference between an output signal being output from the filter group and a predetermined value of the output signal.

### Supplementary Note 18

A non-transitory computer readable medium configured to store a program for causing a processor to execute processing of:
performing compensation for first distortion being included in a reception signal being acquired by coherent-receiving a signal being transmitted from a transmitter via a transmission path, with respect to the reception signal and a complex conjugate signal of the reception signal, by using a first filter;
inputting, to a filter group including a second filter, the reception signal and the complex conjugate signal that are subjected to compensation for the first distortion, and performing compensation for second distortion being included in the reception signal, by using the second filter; and
adaptively controlling a filter coefficient of the second filter, based on a difference between an output signal being output from the filter group and a predetermined value of the output signal.

### REFERENCE SIGNS LIST

10 COMMUNICATION SYSTEM
11 TRANSMITTER
15 RECEIVER
13 TRANSMISSION PATH
21 RECEIVING CIRCUIT
22 EQUALIZATION SIGNAL PROCESSING CIRCUIT
23 FIRST FILTER
24 SECOND FILTER
25 FILTER GROUP
26 COEFFICIENT UPDATING MEANS
100 OPTICAL FIBER COMMUNICATION SYSTEM
110 OPTICAL TRANSMITTER
130 TRANSMISSION PATH
150 OPTICAL RECEIVER
111 ENCODING UNIT
112 PRE-EQUALIZING UNIT
113 DAC
114 OPTICAL MODULATOR
115 LD
132 OPTICAL FIBER
133 OPTICAL AMPLIFIER
151 LD
152 COHERENT RECEIVER
153 ADC
154 EQUALIZING UNIT
155 DECODING UNIT
171 CHROMATIC DISPERSION COMPENSATING FILTER
172 IN-RECEIVER DISTORTION COMPENSATING FILTER
173 POLARIZATION DEMULTIPLEXING FILTER
174 CARRIER PHASE COMPENSATING FILTER
175 IN-TRANSMITTER DISTORTION COMPENSATING FILTER
176 LOSS FUNCTION CALCULATING UNIT
177 COEFFICIENT UPDATING UNIT
178 PLL
179 COMPLEX CONJUGATE CALCULATING UNIT

What is claimed is:

1. An equalization signal processing circuit comprising:
a first filter configured to perform compensation for first distortion being included in a reception signal being acquired by coherent-receiving a signal being transmitted from a transmitter via a transmission path, with respect to the reception signal and a complex conjugate signal of the reception signal, and output the reception signal and the complex conjugate signal that are subjected to compensation for the first distortion;
a filter group including a second filter configured to receive, as input signals, the reception signal and the complex conjugate signal that are subjected to compensation for the first distortion, perform compensation for second distortion being included in the reception signal, and output the reception signal being subjected to compensation for the second distortion;
at least one memory storing instructions; and
at least one processor configured to execute the instructions to adaptively control a filter coefficient of the second filter, based on a difference between an output signal being output from the filter group and a predetermined value of the output signal.

2. The equalization signal processing circuit according to claim 1, wherein the first distortion includes distortion caused by chromatic dispersion in the transmission path, and the first filter compensates for chromatic dispersion.

3. The equalization signal processing circuit according to claim 1, wherein the second distortion includes in-receiver distortion occurring in a receiver, and the second filter compensates for in-receiver distortion.

4. The equalization signal processing circuit according to claim 1, wherein the first filter includes a complex signal input complex coefficient filter having a predetermined tap length, and the second filter includes a multiple input single output (MISO) filter.

5. The equalization signal processing circuit according to claim 4, wherein the MISO filter convolves a first complex coefficient with respect to the reception signal being subjected to compensation for the first distortion, convolves a second complex coefficient with respect to the complex conjugate signal being subjected to compensation for the first distortion, and adds and outputs the reception signal being convolved with the first complex coefficient and the complex conjugate signal being convolved with the second complex coefficient.

6. The equalization signal processing circuit according to claim 1, wherein the signal being transmitted from the transmitter is a polarization multiplexed signal, and the first filter and the second filter are arranged for each polarization.

7. The equalization signal processing circuit according to claim 1, wherein
the filter group includes one or more filters being connected in series along a signal path of the reception signal, on a downstream side with respect to the second filter, and
the at least one processor is configured to execute the instructions to adaptively control the filter coefficient of the second filter by using an error back propagation method.

8. The equalization signal processing circuit according to claim 7, wherein
the one or more filters include a third filter configured to perform compensation for third distortion being included in the reception signal, and
the at least one processor is configured to execute the instructions to adaptively control a filter coefficient of the third filter, based on a difference between an output signal being output from the filter group and a predetermined value of the output signal.

9. The equalization signal processing circuit according to claim 8, wherein the third distortion includes in-transmitter distortion occurring in a transmitter, and the third filter compensates for in-transmitter distortion.

10. A receiver comprising:
a receiving circuit configured to coherent-receive a signal being transmitted from a transmitter via a transmission path; and
the equalization signal processing circuit according to claim 1.

11. The receiver according to claim 10, wherein the first distortion includes distortion caused by chromatic dispersion in the transmission path, and the first filter compensates for chromatic dispersion.

12. The receiver according to claim 10, wherein the second distortion includes in-receiver distortion occurring in a receiver, and the second filter compensates for in-receiver distortion.

13. The receiver according to claim 10, wherein the first filter includes a complex signal input complex coefficient filter having a predetermined tap length, and the second filter includes a multiple input single output (MISO) filter.

14. A communication system comprising:
a transmitter configured to transmit a signal via a transmission path; and
the receiver according to claim 10.

15. The communication system according to claim 14, wherein the first distortion includes distortion caused by chromatic dispersion in the transmission path, and the first filter compensates for chromatic dispersion.

16. The communication system according to claim 14, wherein the second distortion includes in-receiver distortion occurring in a receiver, and the second filter compensates for in-receiver distortion.

17. An equalization signal processing method comprising:
performing compensation for first distortion being included in a reception signal being acquired by coherent-receiving a signal being transmitted from a transmitter via a transmission path, with respect to the reception signal and a complex conjugate signal of the reception signal, by using a first filter;
inputting, to a filter group including a second filter, the reception signal and the complex conjugate signal that are subjected to compensation for the first distortion, and performing compensation for second distortion being included in the reception signal, by using the second filter; and
adaptively controlling a filter coefficient of the second filter, based on a difference between an output signal being output from the filter group and a predetermined value of the output signal.

18. A non-transitory computer readable medium configured to store a program for causing a processor to execute processing of:
performing compensation for first distortion being included in a reception signal being acquired by coherent-receiving a signal being transmitted from a transmitter via a transmission path, with respect to the reception signal and a complex conjugate signal of the reception signal, by using a first filter;
inputting, to a filter group including a second filter, the reception signal and the complex conjugate signal that are subjected to compensation for the first distortion, and performing compensation for second distortion being included in the reception signal, by using the second filter; and
adaptively controlling a filter coefficient of the second filter, based on a difference between an output signal being output from the filter group and a predetermined value of the output signal.
